(19) United States
(12) Patent Application Publication
(10) Pub. No.: US 2012/0053871 A1
(43) Pub. Date: Mar. 1, 2012

(54) Integrated Intelligent Battery Management System and Monitoring System

(76) Inventor: Michael Sirard, Attleboro, MA (US)

(21) Appl. No.: 13/222,882

(22) Filed: Aug. 31, 2011

Related U.S. Application Data
(60) Provisional application No. 61/378,657, filed on Aug. 31, 2010.

(51) Int. Cl. G01R 31/36

(52) U.S. Cl. 702/63

(57) ABSTRACT

The instant invention comprises an intelligent battery management system, wherein the system includes a plurality of batteries with an integrated electronic device, preferably integrated at the time of battery manufacture, disposed to be in data communication with a controller and a monitoring application. The electronic devices are disposed to include a plurality of self-stored information relating to a battery's manufacturing information, along with the ability to perform periodic testing of a plurality of evaluation parameters to determine the health and status of the battery.

### CROSS REFERENCE TO RELATED APPLICATION

This application claims the benefit of and takes priority from Provisional Application Ser. No. 61/378,657 filed on Aug. 31, 2010 the contents of which are hereby incorporated by reference.

### BACKGROUND OF THE INVENTION

1. Field of the Invention

The instant invention relates generally to a battery and an associated management system, and more particularly to a battery management system wherein the system is disposed to integrate an intelligent electronic device within a battery to allow for the storage of a plurality of evaluation parameters, and to provide a periodic measurement and analysis of the battery to the battery management system through a controller.

2. Description of the Related Prior Art

Presently, batteries may be utilized in a variety of applications, and due to the lack of the intelligent battery management system that could provide a better life prediction, concurrent with the batteries use, exists the premature disposal prior to the end of each battery's life.

A typical battery management/maintenance system currently relies on either a failed battery, or a routine replacement of the battery based on the default manufacturing information provided about the battery. This type of system/process may ultimately lead to either a system failure, if the battery is not replaced on time, or if the disposal of a battery occurs prior to the battery's end life. On average, the life of a battery usually depends on its characteristics at the time of manufacturing and as such, these characteristics may change over the course of time, through either a physical environment and/or the usage behavior (i.e. charge/discharge, etc.). Therefore, as a result, each individual battery possesses a different and unique life expectancy in contrast to the standard value indicated by a manufacturer.

Thus, due to the battery management system/maintenance processes that currently exist, a business may experience an increased battery cost coupled with waste of the battery due to premature disposal, to ensure that either a primary and/or a backup battery system is properly functioning at all times, in the event the primary system fails.

### SUMMARY OF THE INVENTION

The instant invention, as illustrated herein, is clearly not anticipated, rendered obvious, or even present in any of the prior art mechanisms, either alone or in any combination thereof.

In order to maximize the usage of the life of a battery in conjunction with reducing the waste of a battery and to reduce the overall cost of battery management, the instant invention provides for a plurality of electronic devices to be preferably integrated to a battery and an overall battery management system. The electronic device of the instant invention possesses a plurality of functionalities and measurement capabilities to allow for the maximization of battery life usage and to manage the cost of a battery system efficiently. Wherein these functionalities include but are not limited to:
i) A plurality of self stored information disposed to be stored within the electronic device;
ii) Periodic measurement and analysis of the battery;
iii) Data and/or electronic communication with the battery management system; and
iv) Battery management system connection reliability.

In one embodiment, the plurality of self stored information contained within an electronic device may include information relating to a battery from the date of manufacture, and periodic measurement information to the end of the battery life. Furthermore, the plurality of self-stored information may include data relating to the electronic device and/or battery identification (i.e. manufacturing date, factory name, location, serial number etc.) type, capacity, measurement data (i.e. resistance and/or emmittance, and/or impedance and/or conductance, voltage, current, temperature) as well as the date of each measurement. As such, in one embodiment, the plurality of self-stored information contained within the electronic device is disposed to create a unique profile for each battery, and thereby minimize the risk of the losing historical information for each battery.

In another embodiment, the periodic measurement and analysis function is disposed to allow for a battery to automatically conduct a self test of a plurality of battery characteristics and battery health, wherein the frequency of measurements may be determined based on the needs of an individual user or the requirements of a system. Once the information obtained from the self-test is obtained by the electronic device, it may be stored in the device for further analysis.

In yet another embodiment, the analysis function of the electronic device may include information requested by a controller, wherein the controller is in data and electronic communication with the overall battery management system. This information may include, but is not limited to the resistance and/or emmittance, the impedance and/or conductance, voltage, current and temperature, wherein the information may be transmitted to the battery management system to provide an estimate on the life of a particular battery within a system. In one embodiment, the analysis function may provide an indication of the health of a battery through a light emitting diode (“LED”) indicator disposed within the battery.

The communication function of the electronic device is disposed to allow for data and electronic communication between a controller and a corresponding battery. In one embodiment, the data communication may either be hard wired, or alternatively communicate through a wireless connection, including but not limited to Bluetooth®, Zigbee® or Radio Frequency Identification (“RFID”). In one embodiment, the controller may be incorporated within the battery management system to allow for remote management, thus allowing for both the measurement and communication function of the electronic device to reduce the cost of routine management of a battery system.

In yet another embodiment, the battery management system connection reliability function requires the use of a permanently affixed connection to an exterior terminal, post, or internal strap of the battery. As such, in order to preserve the integrity of a plurality of battery data, the connection should be permanent to insure a consistent connection.

Therefore, by integrating the electronic device into a battery, and within the battery management system as previously described, the cost and safety concerns from the implementation after a battery has been taken into use can be significantly reduced while the external factors affecting the measurement accuracy may be kept to a minimum. Furthermore, the instant invention utilizes a plurality of data from the electronic devices to monitor and analyze the performance and life expectancy of a plurality of batteries. Moreover, since the plurality of data from the electronic sensors is disposed to be available from the initial manufacturing date of the battery through periodical measurement of the battery, a higher level of accuracy may be achieved in terms of the estimation of the life of a battery contained within a system.

Furthermore, the instant invention may allow for the end-to-end management of the life cycle of a battery through a plurality of unique information created for each battery via a plurality of electronic sensors contained within the battery. Thus, each battery life usage may be maximized by replacing a battery in failure in a timely manner while concurrently reducing battery waste by eliminating premature disposal.

The instant invention provides for the following advantages in several aspects, including but not limited:
i) Inventory management: An inventory management system may be disposed to be in data communication with a plurality of electronic devices, and be able to identify and located a battery that needs to be disposed via the battery identification and similar information disclosed above to create a “First-in, First out” system.
ii) Quality control and Warranty Management: The periodic measurement and information storage function allows a manufacturer to identify a defect battery prior to shipping and dispensing.
iii) Demand/Supply forecast: Budget and forecast may be performed more effectively with better accuracy on the battery life expectancy.
iv) Extend Battery Life: Replacing the individual failure battery in a timely fashion may help to extend the overall battery life of the battery backup system.
v) OPEX Reduction: The instant invention illustrates the value of monitoring a plurality of battery backup power assets on an individual basis, thus allowing a user to replace only the backup assets that are failing when needed instead of replacing all backup batteries in an existing system when one battery fails.
vi) Higher Accuracy and Efficiency Battery Maintenance Practice: The instant invention is disposed to provide a more comprehensive and frequent measurement data (i.e. daily rather than quarterly) for both trend analysis and correlation, and thus reducing human errors in battery management.
vii) Recycle and Waste Management System: The better prediction of the battery life, the less waste produces which is better for the environment.

There has thus been outlined, rather broadly, the more important features of an intelligent battery management and monitoring system in order that the detailed description thereof that follows may be better understood, and in order that the present contribution to the art may be better appreciated. There are additional features of the invention that will be described hereinafter and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

These together with other objects of the invention, along with the various features of novelty, which characterize the invention, are pointed out with particularity in the claims annexed to and forming a part of this disclosure. For a better understanding of the invention, its operating advantages and the specific objects attained by its uses, reference should be made to the accompanying drawings and descriptive matter in which there are illustrated preferred embodiments of the invention.

### BRIEF DESCRIPTION OF THE DRAWINGS

FIG. 1 illustrates one embodiment of the instant invention, wherein an electronic device is disposed to be integrated into the battery monitoring system via a battery thereby allowing for the device to be in data and electronic communication with a controller.

FIG. 2 illustrates one embodiment of the instant invention, wherein an electronic device is disposed to be integrated into the battery monitoring system during production to allow for data communication with a controller and monitoring system to provide an end-to-end management process of a plurality of batteries.

FIGS. 3-6 illustrate various embodiments of the types of battery connections which may be utilized with the instant invention.

FIGS. 7-8 illustrate various embodiments of both internal and external mounting of the instant invention via a battery.

FIG. 9 illustrates one embodiment of a flow diagram for a management process of a battery utilizing the instant invention.

### DETAILED DESCRIPTION OF THE PREFERRED EMBODIMENT

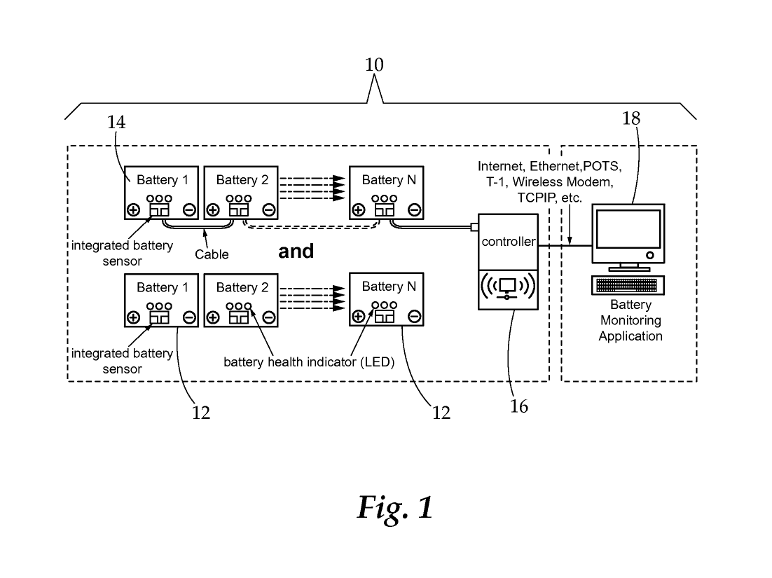

FIG. 1 illustrates the instant invention 10, wherein the instant invention encompasses an intelligent battery monitoring and management system. In one embodiment, the system 10 includes a plurality of electronic devices 12, wherein the electronic devices are preferably located within a battery 14. In one embodiment, the devices 12 may be located either internally within the battery 14, or externally on the battery 14. Furthermore, the system 10 further comprises a controller 16, wherein the controller 16 is in data and electronic communication with the plurality of electronic devices 12. In one embodiment, the data and electronic communication between the controller 16 and the plurality of electronic devices 12 may be either wireless, including but not limited to Bluetooth® and Zigbee®, or hard wired. Additionally, the system 10 may include a battery monitoring application 18, wherein the monitoring application 18 is in data and electronic communication with the controller 16. As discussed above, the plurality of electronic devices 12 are disposed to perform a variety of functions, including, but not limited to:
i) A plurality of self stored information disposed to be stored within the electronic device;
ii) Periodic measurement and analysis of the battery;
iii) Data and/or electronic communication with the battery management system; and
iv) Battery management system connection reliability.

In one embodiment, the controller 16 and the monitoring application 18 are disposed to collect a plurality of information measured and stored by the electronic devices 12. Furthermore, the plurality of electronic devices 12 are disposed to perform a periodic measurement of a variety of evaluation parameters for each batter 14 contained within the overall system 10 according to either a pre-determined schedule, or a command transmitted from either the controller 16 and/or monitoring application 18.

In yet another embodiment, the electronic devices 12 are disposed to store the measurement data collected for a pre-determined amount of time, according to either an individual user of the system 10 or a specific use of the system 10. Preferably, the self-stored information contained within the electronic device 12 includes, but is not limited to data pertaining to the battery 14, beginning from the date of the manufacture, through each periodic measurement, all the way to the end of life of the battery 14. Furthermore, the self-stored information contained with the electronic devices 12 may include both identification information for the electronic device 12 and the battery 14 attached with the electronic device 12, including, but not limited to manufacturing date, factory name, location, serial number, type, capacity. Moreover, the measurement data contained within the self-stored information of the electronic device 12 includes but is not limited to: resistance and/or emmitance, impedance and/or conductance, voltage, current and temperature, along with recording the date of each measurement and evaluation parameter. In one embodiment, if the storage capacity of the electronic device 12 is near or at capacity, the oldest data excluding the identification may be purged from the electronic device 12.

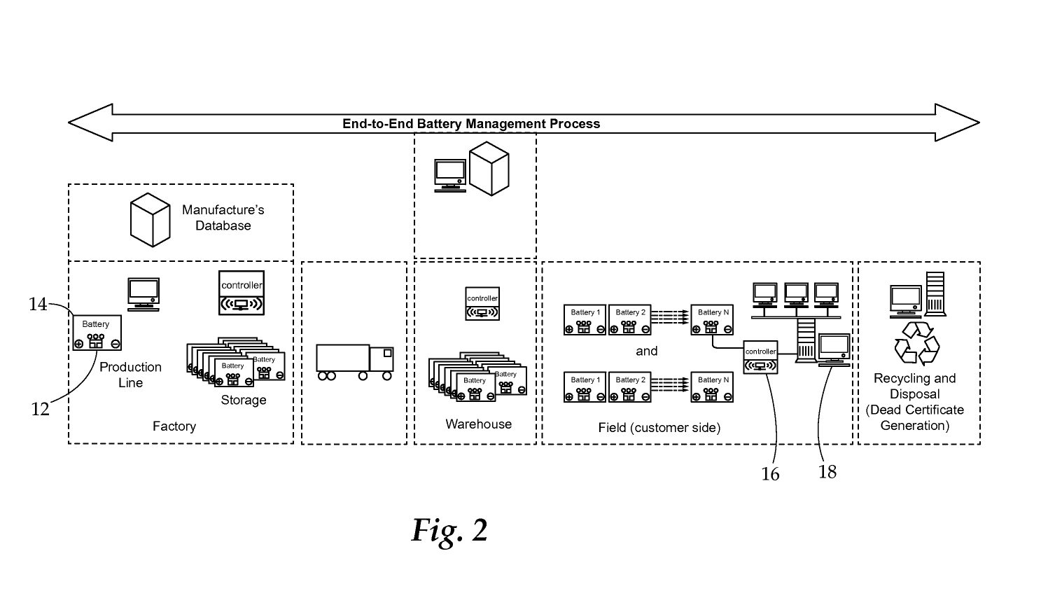

FIG. 2 illustrates one embodiment of the instant invention, wherein the electronic device 12 is disposed to be integrated into the battery monitoring system 10 during production to allow for data communication with the controller 16 and monitoring application 18 to preferably provide an end-to-end management process of a plurality of batteries 14. In this embodiment, the electronic device 12 may be integrated into the system 10 at the time of manufacture or shortly after post manufacturing.

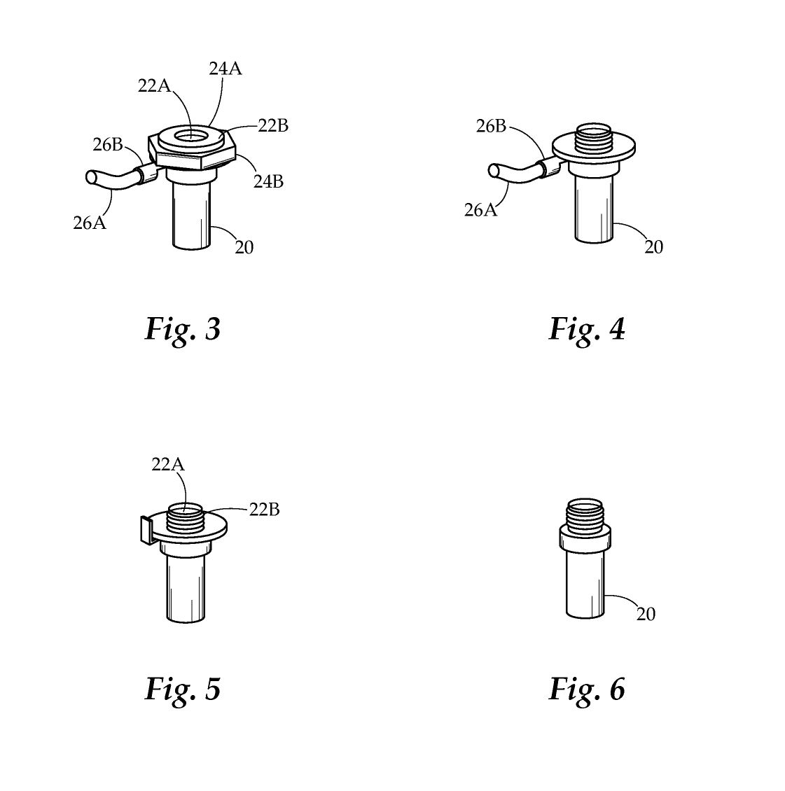

FIGS. 3-6 illustrate various embodiments of the types of battery 14 connections which may be utilized with the instant invention. In each connection embodiment, a post 20 preferably is provided for placement within the battery 14; the post 20 further includes an inner thread 22A and an outer thread 22B. In one embodiment, the outer thread 22B is disposed to receive a terminal bolt 24A and a terminal nut 24B preferably for securing a connection 26A and a connection terminal 26B between the post 20 and the electronic device 12. Therefore, by allowing for the various connections disclosed above, the connections will most likely insure consistent and uniform readings over time of the evaluation parameters.

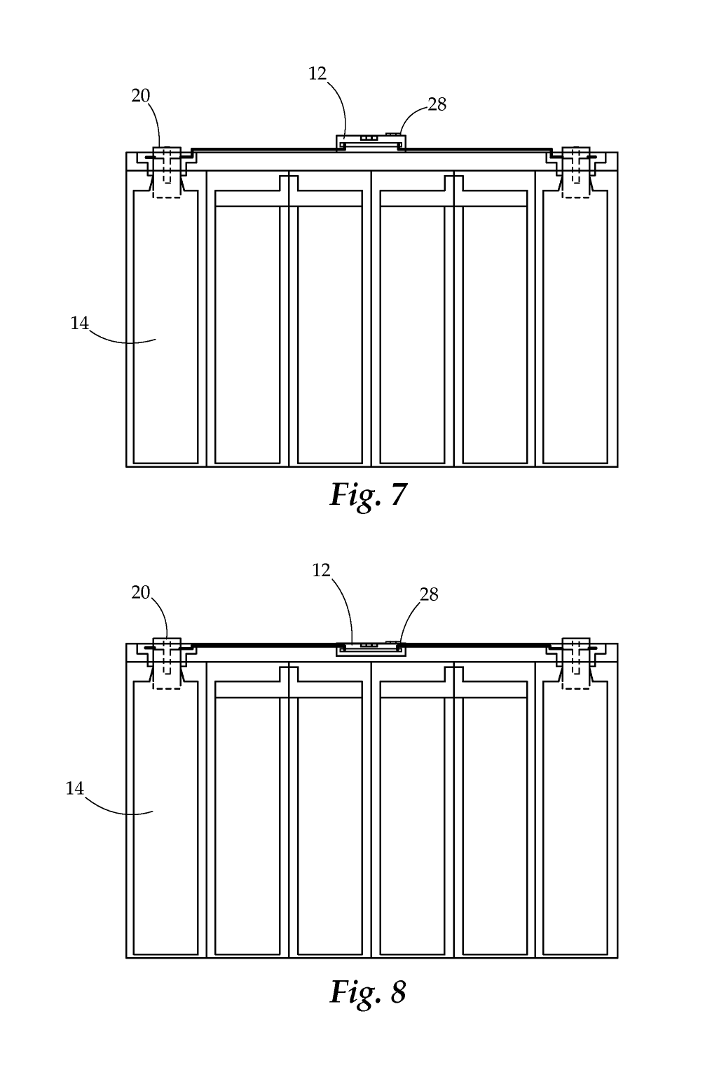

FIGS. 7-8 illustrate various embodiments of both internal and external mounting of the instant invention via a battery 14, wherein the electronic device 12 may be attached to the battery 14 on either the top, side or incorporated as part of a battery cover. In one embodiment, the electronic device 12 is disposed for connection to the battery 14 through various means, including, but not limited to the positive and negative terminals, the positive and negative posts, the positive and negative strap, or the positive and negative battery terminal bar. Furthermore, the connection of the electronic device 12 and/or a lead of the electronic device 12 may be independent of the battery's terminal connection utilized to connect a plurality of batteries in series or to a bus. Additionally, the connection preferably consists of a permanent soldered connection to the post, strap, or terminal.

In one embodiment, the plurality of electronic devices 12 of the instant invention preferably will utilize a visual identification to provide a status indication of the battery 14, such as a light emitting diode (“LED”) 28 or other similarly function LED device. In alternate embodiments, the electronic device 12 is disposed to incorporate a method for standalone direct retrieval of battery information via USB, Fire wire Serial or other communication protocol. The electronic device 12 may utilize a unique fixed serialized identification number, in addition to optionally incorporating a quick connect methodology for attaching a circuit board of the electronic device 12 to the terminals of the battery 14.

In addition, the electronic device 12 includes the following optional elements and/or embodiments:
i) The electronic device 12 may utilize a probe, sensor or thermostat to thermocouple and measure the temperature of the battery 14 at either the battery terminals, posts and/or the vent head space of the battery, and/or within the internal confines of the battery cell;
ii) The electronic device 12 may be constructed within the battery container or cover for upgrading or for replacement;
iii) The electronic device 12 may be molded into the cover or container of the battery 14;
iv) The electronic device 12 is disposed to measure and analyze various electrical parameters and electronic test measurements to determine the health and status of a plurality of batteries 14;
v) The electronic device 12 may utilize a wireless communication device to provide battery health status and/or electrical parameters remotely; and
vi) The electronic device 12 may utilize a wired and/or wireless connection for communication that is auto deductable; in the event a wired connector cable is not present, then the wireless connection may be enabled.

In yet another embodiment, and in additional to evaluation parameters previously disclosed, the electronic device 12 is device measure and/or store at least one of the following parameters of a battery 14, including, but not limited to:
i) Battery ID;
ii) Model;
iii) Production Location;
iv) Production Date Code;
v) Open circuit voltage;
vi) Internal resistance;
vii) Actual voltage value;
viii) Nominal Ah value;
ix) Actual Ah value;
x) Number of discharge(s);
xi) Discharge length of time;
xii) Discharge(s) current;
xiii) Battery terminal temperature;
xiv) Battery internal cell temperature;
xv) Calculated state of health value;
xvi) Max daily temperature(s);
xvii) Electronic device serial number;
xxiii) Battery serial number;
xix) Battery Ah capacity;
xx) Battery nominal Ah capacity;
xxi) Battery constant power rating;
xxii) Battery internal resistance value; and
xxiii) Other battery ohmic test or AC voltage/frequency information analysis.

Furthermore, the plurality of electronic devices 12 of the system 10 are disposed to be in data communication with either the controller 16 and/or the monitoring application 18 in several embodiments, including, but not limited to:
i) A direct wired connection utilizing a USB, firewire, Ethernet, DIN and/or any single or multi-pin connect ion or another direct wire electronic data communication protocol; and
ii) A wireless communication connection, wherein the wireless communication mode includes, but is not to limited to Zigbee®, RFID, Bluetooth®, or any another similarly functioning wireless electronic data communication protocol.

Moreover, the electronic device 12 should be replaceable in order to replace a defective device 12 without needing to dispose of the entire battery 14. In one embodiment, the manufacturer of a battery 14 possesses the ability to download an individual battery's profile to the electronic device 12 prior to storing the battery 14 in a warehouse or shipping to the local supplier/customer.

As discussed above, each unique battery 14 profile and electronic device 12 profile such as device 12 and battery 14 identification (manufacturing date, factory name, location, serial number and the like), type, capacity, measurement data (resistance and or emmitance and or impedance and or conductance, voltage, current and temperature, etc.) may be stored in a manufacture's database system for future purpose. Thus, for example if the electronic device 12 fails prior to the end life of the battery 14, the supplier or customer is able to download the unique battery 14 profile from the manufacturer's database to a new electronic device 12, in combination with replacing the defected device 12 as opposed to disposing of the entire battery 14.

Therefore, in one embodiment, when a battery 14 is situated in either a warehouse or during shipping, the electronic device periodically performs self testing of the health of the battery 14 according to a predefined schedule or signal from the controller 16 and/or monitoring application 18, and stores the measurement of the evaluation parameters within the electronic device 12. This embodiment allows the option for either a battery manufacturer and/or a local battery supplier to obtain the measurement data from the electronic device 12 or the monitoring application 18 regularly by having the controller 16 installed in the warehouse, and using the battery ID, electronic device ID, or combined Battery 14 and electronic device 12 ID in the controller 16 or monitoring application 18. This may be realized when the communication between the controller 16 and electronic device is accomplished utilizing wireless technology. The measurement data from the electronic devices 12 may be utilized in a variety of applications, including, but not limited to:
i) Inventory management—for example first in first out—the oldest battery shall be shipped first;
ii) Battery health monitoring and quality control—identify defect battery(s) before delivering to the customer; and
iii) Improve quality and the battery life by charging the battery when necessary.

Therefore, the instant invention provides for a low cost, accurate and real time battery health and performance monitoring system and device which may be realized in one embodiment by the following:
i) Installing the controller 16 at the site of manufacture of the battery 14;
ii) Establishing data communication between the controller 16 and the electronic device 12;
iii) Uploading the unique battery profile and available battery health test results from the battery 14 to the electronic device 12;
iv) Defining a new battery health testing schedule through the controller 16 or monitoring application 18 if a customer or end user desires to change the pre-determined schedule; and
v) Optionally, connecting the customer monitoring application with a supplier's monitoring application.

Following integration of the system 10, the customer monitoring system 10 enables maintenance personnel to undertake numerous functions, including, but not limited to:
i) Perform battery health trending analysis;
ii) Analyze the battery quality;
iii) Prevent the unnecessary system downtime due to failure of battery backup system;
iv) Forecast and plan the battery replacement efficiently;
v) Minimize the waste by avoiding scrapping the good batteries before its end of life; and
vi) Quickly generate the battery dead certificate when a battery comes to the end of life and is sent for disposal/recycle from the unique batter profile storing in the battery monitoring system.

The unique battery information that is made available from the instant invention enables the customer to maximize the usage of the battery life, to minimize the battery waste, and to reduce the overall cost of battery management. In addition, the information allows the manufacturer to improve the demand-supply chain, and the research and development in battery performance and quality which in turn, further minimize the battery waste to the global environment.

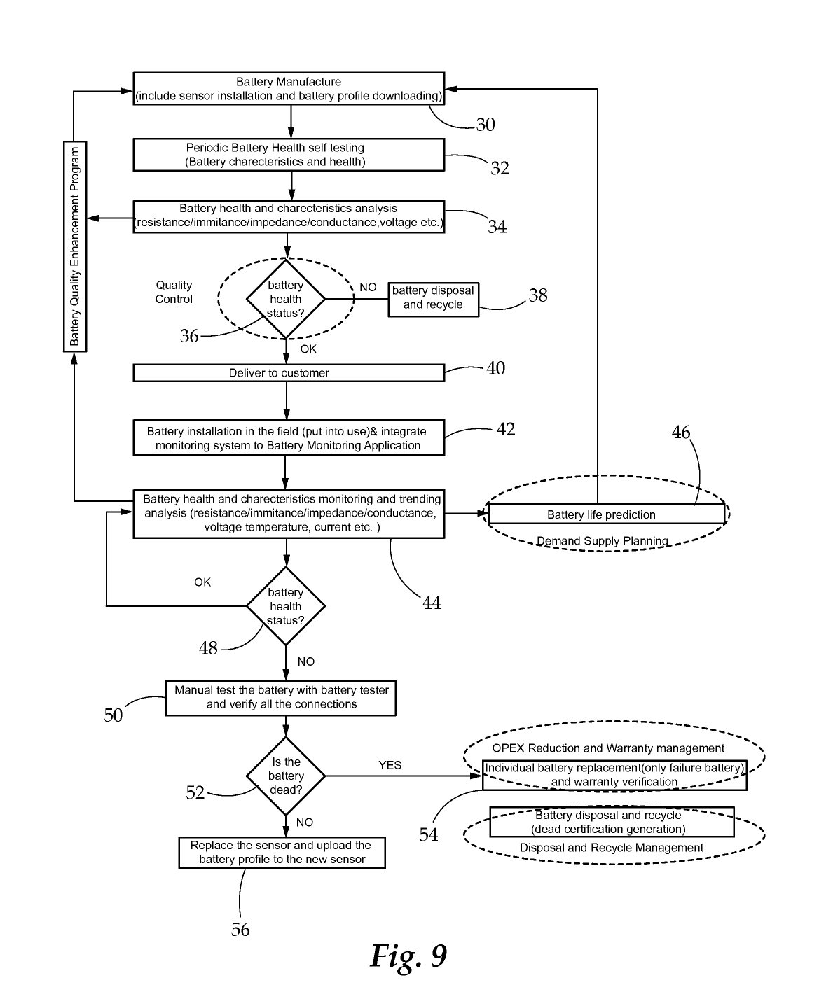

FIG. 9 illustrates a flow diagram for one embodiment of management process for a plurality of batteries utilizing the instant invention. Initially, at step 30, during the manufacture of a battery 14, a plurality of electronic devices may be integrated within the battery 14; furthermore, if a battery profile is available, a manufacturer downloads the profile to the electronic device 12. Subsequently, at step 32, the electronic devices 12 perform periodic testing and measurement of a plurality of evaluation parameters of the battery 14. At step 34, the system 10 is disposed to interpret and/or analyze the plurality of evaluation parameters of the battery stored by the electronic device to determine the health of the battery. At step 36, a determination regarding the status and health of the battery; if the battery is determined not to possess a pre-determined level of health, then at step 38, the battery 14 is disposed. However, if the battery possesses the pre-determined level of health, then at step 40, the battery 14 is delivered to a customer or local supplier. At step 42, the battery delivered to the customer is installed and the electronic device 12 is integrated into a monitoring application 18. Following integration, at step 44, the monitoring application 18 in conjunction with the electronic devices 12 on each battery 14, perform periodic self-testing of each battery 14, along with generating trend analysis for each evaluation parameter. At step 46, a battery life prediction is created for each battery 14 within the system 10 based on the trend analysis generated at step 44, and to allow for download by a manufacturer at step 30. At step 48, the health and status of the battery 14 is determined based on the monitoring and testing performed at step 44; if the health of the battery 14 possesses a pre-determined level of health, then periodic testing continues. However, if the battery 14 does not possess a pre-determined level of health, then at step 50, the battery in question is manually tested with a separate battery tester, along with verifying each connection between the battery and electronic device 12. At step 52, there is a determination if the battery 14 in question is dead; if the battery 14 is dead, then at step 54, the battery 14 is replaced. However, if the battery 14 is not dead at step 52, then at step 56, the electronic device 12 is replaced, and the battery profile is uploaded to a new electronic device 12.

Therefore, in summary the instant invention discloses a variety of unique solutions for the secure pairing and operation of between a device and a data transfer medium through a secure information exchange device located on the device, which is disposed to function as a trusted element that the device and the data transfer medium utilize to establish and to operate in a secure encrypted method.

While several variations of the present invention have been illustrated by way of example in preferred or particular embodiments, it is apparent that further embodiments could be developed within the spirit and scope of the present invention, or the inventive concept thereof. However, it is to be expressly understood that such modifications and adaptations are within the spirit and scope of the present invention, and are inclusive, but not limited to the following appended claims as set forth.

We claim:

1. An intelligent battery management and monitoring system comprising:
a plurality of electronic devices, wherein the electronic devices are disposed to be integrated within a plurality of corresponding batteries;
a controller, wherein the controller is in data communication with the electronic devices; and
a monitoring application, wherein the application is in data communication with the controller.

2. The system of claim 1, wherein each electronic device is disposed to possess a plurality of self-stored information.

3. The system of claim 2, wherein the self-stored information includes at least one parameter selected from the group consisting of data relating to the electronic device identification, data relating to battery identification, and measurement data.

4. The system of claim 3, wherein the identification data of both the electronic device and the battery include at least one parameter selected from the group consisting of manufacturing date, factory name, location, and serial number.

5. The system of claim 3, wherein the measurement data includes at least one parameter selected from the group consisting of type, capacity, resistance, emmittance, impedance conductance, voltage, current, and temperature.

6. The system of claim 1, wherein the electronic device is disposed to perform periodic measurement and analysis of a plurality of evaluation parameters of each battery in the system.

7. The system of claim 1, wherein each electronic device is disposed to be in data communication with the management system for the establishment of each battery's status and health.

8. The system of claim 6, wherein the electronic device is disposed to generate a unique profile for each battery based on the measurement and analysis of the plurality of evaluation parameters.

9. The system of claim 8, wherein each individual battery profile is downloaded to the corresponding electronic device prior to storing the battery in a warehouse or shipping to an individual user.

10. The system of claim 1, wherein each electronic device includes a unique identification number.

11. The system of claim 1, wherein each corresponding battery includes a unique identification number.

12. The system of claim 3, wherein the electronic devices are disposed to store the plurality of evaluation parameters for each battery in a database.

13. The system of claim 1, wherein each electronic device is disposed to capture and store in a plurality of data storage module within the electronic device measurement and analysis data of each battery and associated performance.

14. The system of claim 1, wherein each electronic device is integrated into each corresponding battery at a location selected from the group consisting of a post, a terminal and a strap.

15. The system of claim 1, wherein the system further comprises a temperature measuring device disposed to measure the internal and terminal temperature of each battery.

16. The system of claim 1, wherein the system is disposed to distinguish between open circuit self-discharge and load based discharge.

17. A method of battery management comprising the steps of:
integrating a plurality of electronic devices within a battery during manufacturing of the batter;
performing a periodic measurement by the electronic devices of a plurality of evaluation parameters for the battery;
determining the health of the battery based on the evaluation parameters; and
integrating the battery into a battery monitoring application.

18. The method of claim 17, further comprising the steps of:
performing periodic self-testing of each battery associated with the battery monitoring system by the electronic devices;
generating a trend analysis for each evaluation parameter for the battery; and
creating a battery life prediction for each battery based on the trend analysis generated.

19. The method of claim 18, further comprising the steps of:
determining the health of each battery associated with the battery monitoring system;
evaluating if each battery possesses a pre-determined level of health;
continuing periodic testing if the battery possesses a pre-determined level of health; and
replacing the battery if it fails to possess a predetermined level of health.
